(19) United States
(12) Patent Application Publication
(10) Pub. No.: US 2025/0343543 A1
(43) Pub. Date: Nov. 6, 2025

(54) EVALUATION CIRCUIT FOR A POWER DEVICE WITH AN INTEGRATED SENSOR

(71) Applicant: Infineon Technologies Austria AG, Villach (AT)

(72) Inventors: Anton MAUDER, Kolbermoor (DE); Daniele MIATTON, Carbonara al Ticino (IT); Tobias SIMMET, München (DE); Lorenzo BRUNO, München (DE)

(21) Appl. No.: 19/176,847

(22) Filed: Apr. 11, 2025

(30) Foreign Application Priority Data
May 3, 2024 (DE) 102024204151.3

(51) Int. Cl. H03K 17/082

(52) U.S. Cl. CPC H03K 17/0822; H03K 2217/0027; H03K 2217/0063; H03K 2217/0072

(57) ABSTRACT

A method includes evaluating a first parameter, a second parameter, and third parameter of a power switch. A first evaluation mode includes receiving a first sense current at a common sensing terminal from the power switch; and measuring the first parameter during a switching event of the power switch based on the first sense current. A second evaluation mode includes outputting a second sense current from the common sensing terminal to the power switch; and measuring the second parameter, which is dependent on a current flow of the second sense current through the power switch, the current flow depending on an electrode voltage present at a drain or a collector of the power switch. A third evaluation mode includes generating a third sense current at the common sensing terminal; and measuring the third parameter, which is generated based on the third sense current and a temperature of the power switch.

### CROSS-REFERENCE TO RELATED APPLICATION

This application claims priority to Germany Patent Application No. 102024204151.3 filed on May 3, 2024, the content of which is incorporated by reference herein in its entirety.

### BACKGROUND

Many functions of modern devices in automotive, consumer, and industrial applications, such as driving an electric motor or an electric machine, rely on power semiconductor devices. For example, insulated gate bipolar transistors (IGBTs), metal oxide semiconductor field effect transistors (MOSFETs), and diodes, to name a few, have been used for various applications including, but not limited to, switches in power supplies and power converters.

A transistor typically comprises a semiconductor structure configured to conduct a load current along a load current path between two load terminal structures of the transistor. Further, the load current may be controlled by a control electrode, sometimes referred to as a gate electrode, of the transistor. For example, upon receiving a corresponding control signal from, for example, a gate driver, the control electrode may set its transistor in one of a conducting state or a blocking state. Accordingly, the semiconductor structure behaves like a switch with on- and off-states (i.e., conducting and blocking states, respectively).

Usually, a power inverter is composed of two complementary transistors (e.g., a high-side transistor and a low-side transistor) for each motor phase, where the two complementary transistors form a half-bridge to drive an output pad connected to a motor winding. A gate driver, used for driving the two complementary transistors, may be supplied with a fixed positive voltage and a fixed negative voltage with respect to a reference voltage of each of the two complementary transistors. A positive supply rail may be connected to the output pad via the high-side transistor of the two complementary transistors to supply load current to the motor winding, and the negative supply rail may be connected to the output pad via the low-side transistor of the two complementary transistors to sink load current from the motor winding. The two complementary transistors may be complementarily turned on and off to avoid cross-conduction.

Accordingly, the load current, also referred to as a motor phase current, may be controlled by driving the two complementary transistors. The amplitude of the control signal received from the gate driver for each transistor may be varied to drive the two complementary transistors between switching states. This, in turn, drives the motor. For example, a gate-source voltage Vgs of a MOSFET is typically driven down to approximately zero to turn off the MOSFET and is typically driven to a maximum value to fully turn on the MOSFET. For this reason, the gate-source voltage Vgs may be referred to as a control voltage.

### SUMMARY

In some implementations, a system includes an evaluation circuit configured to evaluate a first parameter of a power switch according to a first evaluation mode and evaluate a second parameter of the power switch according to a second evaluation mode, the evaluation circuit comprising: a return terminal configured to be coupled to an auxiliary sense terminal of the power switch; a common sensing terminal configured to be coupled to a sense terminal of the power switch; a first measurement circuit coupled to the return terminal and the common sensing terminal, and configured to operate during the first evaluation mode, wherein the first measurement circuit is configured to receive a first sense current at the common sensing terminal from the power switch, and measure the first parameter during a switching event of the power switch based on the first sense current; and a second measurement circuit coupled to the return terminal and the common sensing terminal, and configured to operate during the second evaluation mode, wherein the second measurement circuit is configured to output a second sense current from the common sensing terminal to the power switch, and measure the second parameter, which is dependent on a current flow of the second sense current through the power switch, and wherein the current flow of the second sense current through the power switch depends on an electrode voltage present at a second load electrode of the power switch.

In some implementations, a system includes an evaluation circuit configured to evaluate a first parameter of a power switch according to a first evaluation mode and evaluate a second parameter of the power switch according to a second evaluation mode, the evaluation circuit comprising: a return terminal configured to be coupled to an auxiliary sense terminal of the power switch; a common sensing terminal configured to be coupled to a sense terminal of the power switch; a first measurement circuit coupled to the return terminal and the common sensing terminal, and configured to operate during the first evaluation mode, wherein the first measurement circuit is configured to receive a first sense current at the common sensing terminal from the power switch, and measure the first parameter during a switching event of the power switch based on the first sense current; and a second measurement circuit coupled to the return terminal and the common sensing terminal, and configured to operate during the second evaluation mode, wherein the second measurement circuit is configured to generate a second sense current at the common sensing terminal, and measure the second parameter, which is generated based on the second sense current and a temperature of the power switch.

In some implementations, a system includes an evaluation circuit configured to evaluate a first parameter of a power switch according to a first evaluation mode and evaluate a second parameter of the power switch according to a second evaluation mode, the evaluation circuit comprising: a return terminal configured to be coupled to an auxiliary sense terminal of the power switch; a common sensing terminal configured to be coupled to a sense terminal of the power switch; a first measurement circuit coupled to the return terminal and the common sensing terminal, and configured to operate during the first evaluation mode, wherein the first measurement circuit is configured to generate a first sense current at the common sensing terminal, and measure the first parameter, which is generated based on the first sense current and a temperature of the power switch; and a second measurement circuit coupled to the return terminal and the common sensing terminal, and configured to operate during the second evaluation mode, wherein the second measurement circuit is configured to output a second sense current from the common sensing terminal to the power switch, and measure the second parameter, which is dependent on a current flow of the second sense current through the power switch, and wherein the current flow of the second sense current through the power switch depends on an electrode voltage present at a second load electrode of the power switch.

In some implementations, a method includes evaluating a first parameter of a power switch according to a first evaluation mode, including: receiving a first sense current at a common sensing terminal from the power switch; and measuring the first parameter during a switching event of the power switch based on the first sense current; evaluating a second parameter of the power switch according to a second evaluation mode, including: generating a second sense current; outputting the second sense current from the common sensing terminal to the power switch; and measuring the second parameter, which is dependent on a current flow of the second sense current through the power switch, wherein the current flow depends on an electrode voltage present at a drain or a collector of the power switch; and evaluating a third parameter of the power switch according to a third evaluation mode, including: generating a third sense current at the common sensing terminal; and measuring the third parameter, which is generated based on the third sense current and a temperature of the power switch.

### BRIEF DESCRIPTION OF THE DRAWINGS

Implementations are described herein making reference to the appended drawings.

FIG. 1 shows a semiconductor power device according to one or more implementations.

FIG. 2 shows a schematic diagram of a system according to one or more implementations.

FIG. 3 shows a diagram of example evaluation schemes relative to switching states of a power switch according to one or more implementations.

FIG. 4 shows a schematic diagram of a system according to one or more implementations.

FIG. 5 shows a schematic diagram of a system according to one or more implementations.

FIG. 6 shows a schematic diagram of a system according to one or more implementations.

FIG. 7 is a flowchart of an example process associated with evaluation circuit for a power device with an integrated sensor.

### DETAILED DESCRIPTION

In the following, details are set forth to provide a more thorough explanation of example implementations. However, it will be apparent to those skilled in the art that these implementations may be practiced without these specific details. In other instances, well-known structures and devices are shown in block diagram form or in a schematic view, rather than in detail, in order to avoid obscuring the implementations. In addition, features of the different implementations described hereinafter may be combined with each other, unless specifically noted otherwise.

Further, equivalent or like elements or elements with equivalent or like functionality are denoted in the following description with equivalent or like reference numerals. As the same or functionally equivalent elements are given the same reference numbers in the figures, a repeated description for elements provided with the same reference numbers may be omitted. Hence, descriptions provided for elements having the same or like reference numbers are mutually interchangeable.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In implementations described herein or shown in the drawings, any direct electrical connection or coupling (e.g., any connection or coupling without additional intervening elements) may also be implemented by an indirect connection or coupling (e.g., a connection or coupling with one or more additional intervening elements, or vice versa) as long as the general purpose of the connection or coupling (e.g., to transmit a certain kind of signal or to transmit a certain kind of information) is essentially maintained. Features from different implementations may be combined to form further implementations. For example, variations or modifications described with respect to one of the implementations may also be applicable to other implementations unless noted to the contrary.

As used herein, the terms “substantially” and “approximately” mean “within reasonable tolerances of manufacturing and measurement.” For example, the terms “substantially” and “approximately” may be used herein to account for small manufacturing tolerances or other factors (e.g., within 5%) that are deemed acceptable in the industry without departing from the aspects of the implementations described herein. For example, a resistor with an approximate resistance value may practically have a resistance within 5% of the approximate resistance value. As another example, a signal with an approximate signal value may practically have a signal value within 5% of the approximate signal value.

In the present disclosure, expressions including ordinal numbers, such as “first”, “second”, and/or the like, may modify various elements. However, such elements are not limited by such expressions. For example, such expressions do not limit the sequence and/or importance of the elements. Instead, such expressions are used merely for the purpose of distinguishing an element from the other elements. For example, a first box and a second box indicate different boxes, although both are boxes. For further example, a first element could be termed a second element, and similarly, a second element could also be termed a first element without departing from the scope of the present disclosure.

A transistor can be referred to as a power switch or a transistor switch that may be used to drive a current, such as a load current. In particular, a power transistor is a power semiconductor device that may be used to drive a load current. The power transistor includes a first load terminal or a first load electrode (e.g., a source or an emitter) and a second load terminal or a second load electrode (e.g., a drain or a collector). Additionally, a load current path of the power transistor may be controlled by a control electrode, sometimes referred to as a gate, connected to a control terminal of the power transistor. A load current path of the power transistor is a gate-controlled conductive channel whose conductivity may be controlled by a control signal (e.g., a control current or a control voltage) applied to the control electrode of the power transistor. For example, the power transistor can be turned on or off by activating and deactivating its control electrode. For example, applying a positive voltage across a gate and a source of a MOSFET will keep the MOSFET in its “on” state, while applying a voltage of approximately zero or slightly negative across the gate and the source of the MOSFET will cause the MOSFET to turn “off.”

There is a turn-on process and a turn-off process for switching a transistor on and off. During the turn-on process of an n-channel transistor, a gate driver may be used to provide (source) a gate current (e.g., an ON current) to a gate of the n-channel transistor in order to charge a gate voltage to a sufficient voltage to turn on the n-channel transistor. In contrast, during the turn-off process of the n-channel transistor, the gate driver is used to draw (sink) a gate current (e.g., an OFF current) from the gate of the n-channel transistor in order to discharge the gate voltage sufficiently to turn off the n-channel transistor. A voltage pulse may be output from the gate driver as a control signal according to a pulse-width modulation (PWM) scheme. Thus, the control signal may be switched between an ON voltage level and an OFF voltage level during a PWM cycle for controlling the n-channel transistor. This in turn charges and discharges gate capacitance to correspondingly modulate the gate voltage to turn on and off the n-channel transistor, respectively.

The opposite is true for a p-channel transistor. The gate driver may be used to draw (sink) a gate current (e.g., an ON current) from a gate of the p-channel transistor in order to discharge the gate voltage to a sufficient voltage to turn on the p-channel transistor. In contrast, during the turn-off process of the p-channel transistor, the gate driver is used to provide (source) a gate current (e.g., an OFF current) to the gate of the p-channel transistor in order to charge the gate voltage of the p-channel transistor sufficiently to turn off the p-channel transistor. A control signal applied to the gate of the p-channel transistor may be switched between an ON voltage level and an OFF voltage level during a PWM cycle for controlling the p-channel transistor. This in turn charges and discharges the gate voltage to turn on and off the p-channel transistor, respectively.

For both n-channel and p-channel transistors, the n-channel and p-channel transistors are off when the gate-source voltage Vgs is approximately a zero value or below a threshold voltage and the n-channel and p-channel transistors are on when the gate-source voltage Vgs is equal to or greater than the threshold voltage.

For driving a load in this manner, two transistors are typically arranged in a half-bridge configuration, including a high-side transistor and a low-side transistor. The high-side transistor may be a p-channel transistor connected to a high-side supply potential and the low-side transistor may be an n-channel transistor connected to a low-side supply potential. In some implementations, the high-side transistor and the low-side transistor may be of a same transistor type (e.g., both n-channel type or both p-channel type).

A load current is said to be a positive load current when the load current is flowing from a half-bridge toward the load, and a load current is said to be negative when the load current is flowing away from the load toward the half-bridge. A high-side transistor, when on, is responsible for conducting a positive load current in order to source the load current to the load while its complementary, low-side transistor is turned off (e.g., the low-side transistor is in blocking or high impedance mode). In order to sink load current from the load, the roles of the high-side and low-side transistors are reversed. Here, the low-side transistor, when on, is responsible for conducting a negative load current in order to sink the load current from the load while its complementary, high-side transistor is turned off (e.g., the high-side transistor is in blocking or high impedance mode). The two complementary transistors are typically switched such that both are not turned on at the same time.

Transistors may include IGBTs and MOSFETs (e.g., Si MOSFETs or SiC MOSFETs), among other examples. It will be appreciated that one type of transistor may be substituted for another type of transistor. In this context, when substituting a MOSFET for an IGBT, the MOSFET's drain may be substituted for the IGBT's collector, the MOSFET's source may be substituted for the IGBT's emitter, the MOSFETs drain-source voltage Vds may be substituted for the IGBT's collector-emitter voltage Vce, and the MOSFET's gate-source voltage Vgs may be substituted for the IGBT's gate-emitter voltage Vge, or vice versa, in any one of the examples described herein.

Silicon carbide (SiC) power switches have significantly smaller chip area compared to silicon (Si) power switches, which may make it more difficult to cool SiC power switches. As a result, evaluating one or more parameters of a power switch may be used to optimize a performance of the power switch and/or detect one or more fault conditions associated with the power switch. For example, there may be an interest in optimizing a control of the power switch for minimizing switching losses and/or improving a performance of the power switch. Minimized switching losses and or improved performance of the power switch may be obtained by adjusting a voltage transient dV/dt that is present at a load terminal (e.g., a drain terminal) of the power switch to an optimum value for all load currents. The voltage transient dV/dt may correspond to a voltage across the power switch. For example, the voltage transient dV/dt may be a drain-source voltage Vds transient of the power switch. Voltage transient dV/dt measurements may be obtained and compared with one or more thresholds to determine an optimized control parameter of the power switch and/or to determine a status of the power switch. However, evaluating the voltage transient dV/dt typically requires additional wiring and may require one or more additional pads or pins at the power switch. The additional wiring and/or pins increase a manufacturing cost and a complexity to the power switch and the gate driver.

Additionally, there may be an interest in monitoring a temperature of the power switch. However, evaluating the temperature typically requires integration of a sensor and an additional pad or pin at the power switch, which may reduce an active area of the power switch and/or increase a manufacturing cost and a complexity to the power switch.

Additionally, there may be an interest in detecting overload and short circuit conditions (e.g., overcurrent conditions) of the power switch, and reducing a response time for detecting and/or responding to the overload and short circuit conditions. One method used for short circuit detection, referred to as a desaturation (DESAT) method, requires a costly diode with at least a same voltage blocking capability as the power switch connected between the gate driver and the drain of the power switch, as well as a large printed circuit board (PCB) area due to creepage and clearance requirements for high voltage. Both the diode and the large PCB area may result in larger distances between the gate driver and the power switch, which impairs control quality since longer electrical connections are vulnerable to more noise and/or longer signal propagation time when compared to shorter electrical connections.

As a result, it may be complicated to monitor one, two, or all three parameters (e.g., voltage transient dV/dt, temperature, and overcurrent) of the power switch in a cost-effective manner and/or without degrading one or more aspects of the power switch.

Some implementations disclosed herein are directed to a system that includes an evaluation circuit configured to monitor one, two, or all three parameters (e.g., voltage transient dV/dt, temperature, and overcurrent) of a power device, such as a power switch, using a single sense electrical connection for sensing the parameters and a single return electrical connection from the power device. The power device may include an integrated sensor that enables the evaluation circuit to sense each parameter based on a respective sensing technique or scheme. The single sense electrical connection, the single return electrical connection, and/or the integrated sensor may minimize a complexity of the power device, while enabling each parameter to be measured and evaluated. As a result, a manufacturing cost may be reduced, as compared to a manufacturing cost of other conventional solutions. The single sense electrical connection, the single return electrical connection, and/or the integrated sensor may reduce an impact on an on-resistance, an active area or a total area of the power device, as compared to an on-resistance of other conventional solutions. The single sense electrical connection, the single return electrical connection, and/or the integrated sensor may minimize an impact on a length of electrical connections between a gate driver and the power device, as compared to a length of electrical connections of other conventional solutions.

While implementations may be described in reference to a MOSFET (e.g., Si MOSFET or SIC MOSFET), the implementations may be applied to other types of semiconductor power devices, such as IGBTs, junction-gate field-effect transistors (JFETs), GaN power switches, gallium oxide (Ga₂O₃) power switches, trench-type power switches, planar-type power switches, merged pin Schottky diodes, pn-diodes, and pure Schottky diodes.

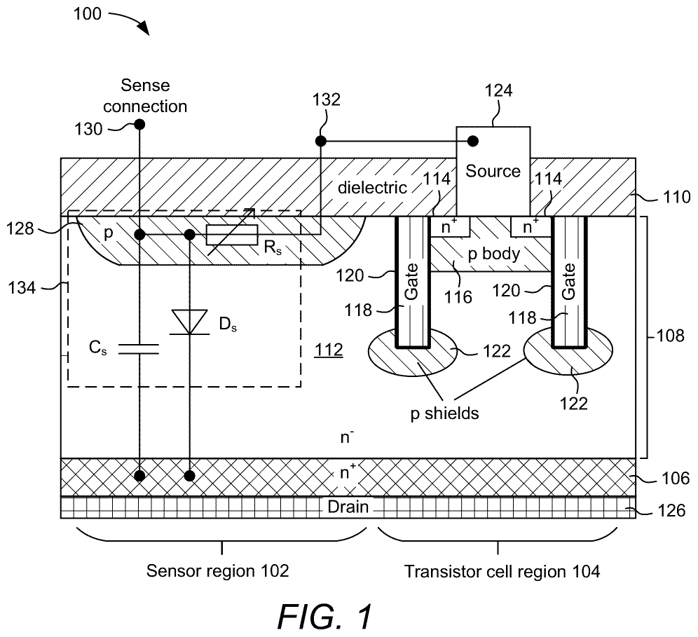

FIG. 1 shows a semiconductor power device 100 according to one or more implementations. The semiconductor power device 100 may be a power switch, such as a SiC trench MOSFET. The semiconductor power device 100 may include a sensor region 102 (e.g., an integrated sensor region), in which an integrated sensor is provided, and a transistor cell region 104, in which a transistor cell is provided. The semiconductor power device 100 may include a drain region 106, a semiconductor body 108 arranged on the drain region 106, and a dielectric layer 110 arranged on the semiconductor body 108. The semiconductor body 108 may include a drift region 112, source regions 114, and a body region 116, which is arranged between the drift region 112 and the source regions 114 and is doped complementarily to the source region 114. One or more gate electrodes 118 are provided for controlling an inversion channel in the body region 116 between the source regions 114 and the drift region 112. The gate electrodes 118 may be dielectrically insulated from the semiconductor body 108 by a gate dielectric 120. Thus, the gate electrodes 118 may be formed in gate trenches that extend into the semiconductor body 108. The gate electrodes 118 may be electrically coupled to a gate driver for receiving a control signal from the gate driver.

The source regions 114 may be arranged in contact with a source electrode 124 (e.g., a first load electrode). The source electrode 124 may extend through the dielectric layer 110 to make contact with the source regions 114. Thus, the source electrode 124 may be insulated from the gate electrodes 118 by the electric layer 110. The body region 116 may be arranged in contact with the source electrode 124. In some implementations, shield regions 122 (e.g., p-shields), doped complementarily to the drift region 112, may be provided at bottom regions of the gate trenches to, for example, prevent gate-to-drain leakage. The shield regions 122 may be electrically coupled to or contacted with the source electrode 124 (not shown in FIG. 1).

The drain region 106, which is adjacent to the drift region 112, may be doped more highly than the drift region 112. The drain region 106 may be arranged in contact with a drain electrode 126 (e.g., a second load electrode). The drain region 106 may be realized by a semiconductor substrate, for example, to which an epitaxial layer with a basic doping is applied. Sections of the epitaxial layer that have the basic doping may form the drift region 112.

The semiconductor power device 100 may be n-conducting (e.g., an n-channel type). In other words, the drain region 106, the drift region 112, and the source regions 114, may be n-doped, while the body region 116 may be p-doped. Alternatively, the semiconductor power device 100 may be p-conducting (e.g., a p-channel type). In other words, the drain region 106, the drift region 112, and the source regions 114, may be p-doped, while the body region 116 may be n-doped.

The source region 114, the body region 116, the drift region 112, and the drain region 106 may be arranged successively in a vertical direction of the semiconductor power device 100. When the transistor cell is driven in the on-state, that is to say when for an n-conducting power semiconductor device a positive voltage is applied between drain and source and a suitable driving potential is applied to the gate electrode 118, a current flows in a vertical direction through the drift region 112 between the source electrode 124 and the drain electrode 126.

In the case of this component, the body region 116 and the drain region 106 form first and second component regions, between which the drift region 112 is arranged, in which case a space charge region propagates in the drift region 112 proceeding from the semiconductor junction between the body region 116 and the drift region 112 when a reverse voltage is applied between the body region 116 and the drain region 112. In some implementations, the semiconductor power device 100 may be a high voltage power switch that has a blocking voltage of at least 300 V. The blocking voltage may be configured, at least in part, based on the thickness and the doping of the drift region 112.

The sensor region 102 may include a doped sensor region 128 integrated in the drift region 112. The doped sensor region 128 may be doped complementarily to the drift region 112. Thus, the doped sensor region 128 may be a p-well or island region that may be used to sense one or more parameters of the semiconductor power device 100.

The doped sensor region 128 may be electrically coupled to a sense terminal 130. Additionally, the doped sensor region 128 and the drift region 112 may form a junction capacitor Cs that is electrically coupled to the sense terminal 130 and the drain electrode 126 of the power switch. Additionally, the doped sensor region 128 and the drift region 112 may form a pn-junction diode Ds having an anode that is electrically coupled to the sense terminal 130 and a cathode that is electrically coupled to the drain electrode 126 of the power switch, in case of an n-conducting power switch. The junction capacitor Cs and the pn-junction diode Ds may be parasitic elements, since the pn-junction diode Ds may be driven in forward conduction in case a voltage at the sense terminal 130 exceeds a diffusion voltage of the pn-junction and the junction capacitor Cs is providing disturbance during switching of the power switch and capacitive coupling to the source electrode 124 and the drain electrode 126.

In some implementations, the doped sensor region 128 may provide a temperature-dependent resistive path that provides an electrical resistance Rs that may vary based on a temperature of the power switch. In some implementations, the temperature-dependent resistive path may be formed between the sense terminal 130 and an auxiliary sense terminal 132 of the semiconductor power device 100. In some implementations, the auxiliary sense terminal 132 may be the source electrode 124 or may be coupled to the source electrode 124. In some implementations, the temperature-dependent resistive path is optional, and therefore may not be present.

The junction capacitor Cs, the pn-junction diode Ds, and the (optional) electrical resistance Rs may form an integrated sensor 134 of the semiconductor power device 100 that may be used in conjunction with an evaluation circuit to measure and/or evaluate one or more parameters of the semiconductor power device 100, such as a voltage transient dV/dt, a drain voltage, a drain-source voltage Vds, a current, and/or a temperature of the power switch. The semiconductor power device 100 (e.g., the power switch) may be a vertical device, and the junction capacitor and the pn-junction diode may be vertically arranged in the vertical device, whereas the temperature-dependent resistive path may extend in a lateral direction.

As indicated above, FIG. 1 is provided merely as an example. Other examples may differ from what is described with regard to FIG. 1.

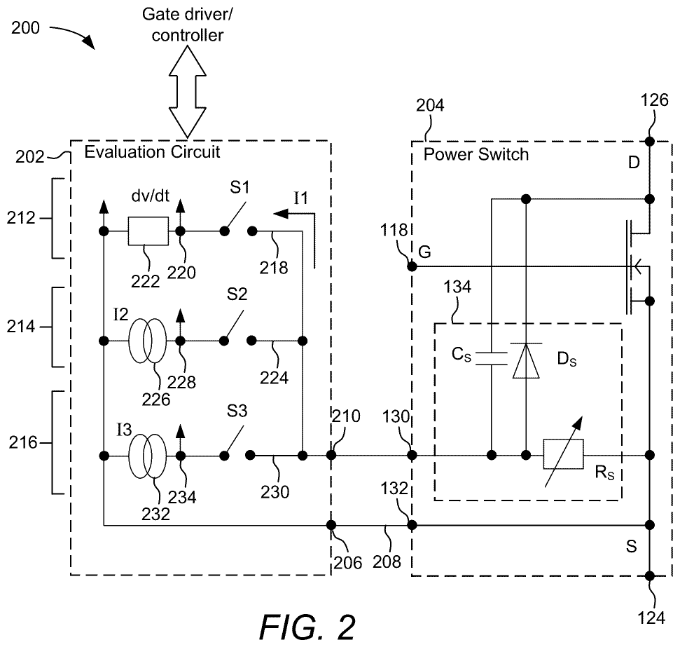

FIG. 2 shows a schematic diagram of a system 200 according to one or more implementations. The system 200 may include an evaluation circuit 202 and a power switch 204. The power switch 204 may be similar to the semiconductor power device 100 described in connection with FIG. 1. Thus, the power switch 204 may include the gate electrode 118, the source electrode 124, the drain electrode 126, the sense terminal 130, the auxiliary sense terminal 132, and the integrated sensor 134 formed by the doped sensor region 128. The elements Cs, Ds and Rs in FIG. 2 are the electrical equivalents to the doped sensor region 128 as lumped circuit elements.

The evaluation circuit 202 may be configured to evaluate a first parameter of a power switch according to a first evaluation mode, evaluate a second parameter of the power switch according to a second evaluation mode, and evaluate a third parameter of the power switch according to a third evaluation mode. The evaluation circuit 202 may evaluate the first parameter, the second parameter, and the third parameter using a single sense electrical connection and a single return electrical connection from the power switch 204. In some implementations, the first evaluation mode is active during a switching event of the power switch 204. For example, the first evaluation mode may be active (enabled) during a turn-on switching event, during which the power switch 204 is transitioned from an off-state to an on-state, and/or during a turn-off switching event, during which the power switch 204 is transitioned from the on-state to the off-state. In some implementations, the second evaluation mode and/or the third evaluation mode may be active outside of the switching events of the power switch 204, when the power switch 204 is in a quasi-static state (e.g., when the power switch 204 is in the on-state or in the off-state). In some implementations, the second evaluation mode and/or the third evaluation mode may be disabled during switching events (e.g., while the first evaluation mode is enabled). In some implementations, the first evaluation mode may be disabled outside of the switching events of the power switch 204 (e.g., while the second evaluation mode and/or the third evaluation mode is enabled). In some implementations, the second evaluation mode and the third evaluation mode may be enabled simultaneously, or may be interleaved in operation (e.g., enabled one at a time in interleaved time slots). In some implementations, only one evaluation mode may be enabled at a time.

In some implementations, the evaluation circuit 202 and the power switch 204 may be integrated on separate dies. In some implementations, the evaluation circuit 202 may be electrically coupled to a gate driver or a controller (not illustrated) to provide measurement data to the gate driver or the controller, and the gate driver or the controller may effect a control of the power switch 204 based on the measurement data (e.g., by regulating a control signal provided to the gate electrode 118). In some implementations, the gate driver or the controller may be part of the evaluation circuit 202, or the evaluation circuit 202 may be integrated in the gate driver or the controller. In some implementations, the gate driver or the controller may perform part of one or more measurement operations in conjunction with the evaluation circuit 202 (e.g., based on measurement signals provided by the evaluation circuit 202).

The evaluation circuit 202 may include a return terminal 206 configured to be coupled to the auxiliary sense terminal 132. For example, the return terminal 206 may be coupled to the source electrode 124 of the power switch 204. The return terminal 206 may be coupled to an electrical return path 208 that is coupled to the source electrode 124. The electrical return path 208 may enable one or more sense currents to flow and/or provide a supply voltage to the evaluation circuit 202. In some implementations, the return terminal 206 may be used as a return for a gate control of the power device 204.

The evaluation circuit 202 may include a common sensing terminal 210 that is coupled to the sense terminal 130 of the power switch 204. Based on an active evaluation mode, the common sensing terminal 210 may be configured to receive one or more sense currents or sense voltages from the integrated sensor 134 of the power switch 204, or provide one or more sense currents or sense voltages to the integrated sensor 134 of the power switch 204.

The evaluation circuit 202 may include a first measurement circuit 212 coupled to the return terminal and the common sensing terminal, and may be configured to operate during the first evaluation mode. The evaluation circuit 202 may include a second measurement circuit 214 coupled to the return terminal and the common sensing terminal, and may be configured to operate during the second evaluation mode. The evaluation circuit 202 may include a third measurement circuit 216 coupled to the return terminal and the common sensing terminal, and may be configured to operate during the third evaluation mode.

The first measurement circuit 212 may be configured to receive a first sense current I1 at the common sensing terminal 210 from the power switch 204, and measure the first parameter during a switching event of the power switch 204 based on the first sense current I1. The first parameter may be representative of a rate-of-change of the electrode voltage present at the drain electrode 126. For example, the first parameter may be representative of the voltage transient dV/dt (e.g., a voltage transient of the drain voltage or the drain-source voltage Vds).

In some implementations, the first measurement circuit 212 may include a first sensing path 218 coupling the common sensing terminal 210 and the return terminal 206. The first sensing path 218 may include a first sense node 220 and a resistive element 222 configured to generate a sense voltage at the first sense node 220 based on the first sense current I1 received at the common sensing terminal 210 from the power switch 204. For example, the sense voltage at the first sense node 220 may depend on a magnitude of the first sense current I1 based on a voltage drop across the resistive element 222. The first measurement circuit 212 may be configured to measure the sense voltage during the switching event to derive the first parameter. The first sensing path 218 may include a first switch S1 that is closed to enable the first measurement circuit 212 and is opened to disable the first measurement circuit 212, based on a desired evaluation mode. In other implementations, the first sensing path 218 may be formed by one or more active elements, such as a current mirror, a current to voltage transducer, or a current to current transducer.

During the first evaluation mode (e.g., while the first measurement circuit 212 is enabled), the junction capacitor Cs may, during the switching event, provide the first sense current I1 to the common sensing terminal 210. The magnitude of the first sense current I1 may be representative of the drain voltage of the power switch 204. The return terminal 206 is coupled to the electrical return path 208, which may enable the first sense current I1 to flow through the first measurement circuit 212 during the first evaluation mode.

The first measurement circuit 212 may be configured to, for example, in conjunction with the gate driver or the controller, regulate the control signal of the power switch 204 based on the first parameter, detect a short circuit based on the first parameter, adapt a dead time of the power switch 204 based on the first parameter, detect a working region of the power switch 204 based on the first parameter, and/or monitor a status of the power switch 204 based on the first parameter.

The second measurement circuit 214 may be configured to output a second sense current I2 from the common sensing terminal 210 to the power switch 204, and measure the second parameter, which is based on a magnitude of the second sense current and/or is dependent on a current flow of the second sense current I2 through the power switch 204. In some implementations, “dependent on a current flow” may refer to how the second sense current I2 divides between two possible current paths in the power switch 204. In some implementations, “dependent on a current flow” may refer to a magnitude of the second sense current I2 (e.g., an amount of current), which may change based on a change in one or more conditions at the power switch 204. The magnitude of the second sense current I2 and/or the current flow of the second sense current I2 through the power switch 204 may depend on an electrode voltage (e.g., drain voltage) present at the drain electrode of the power switch 204. During the second evaluation mode, the pn-junction diode Ds may be configured to conduct the second sense current I2 based on the drain voltage of the power switch 204. While the pn-junction diode Ds conducts the second sense current I2, a small portion of the second sense current I2 may flow through the electrical return path 208, for example, through the electrical resistance Rs of the temperature-dependent resistive path. However, if the drain voltage undergoes a sudden increase, for example, due to an overcurrent condition (e.g., overload or short circuit), the pn-junction diode Ds may enter a blocking state and all of the second sense current I2 will be conducted through the electrical resistance Rs of the resistive path, which would cause a sudden decrease in either the second sense current I2 and/or a sudden increase of a sense voltage at the common sensing terminal 210. Thus, the second parameter may be representative of the drain voltage present at the drain electrode and may be used to detect the overcurrent condition. Electrical resistance Rs is a higher resistive part than the non-linear diode characteristic of the pn-junction diode Ds. If the pn-junction diode Ds enters the blocking state, a current source for the second sense current I2 may get into voltage clamping and not be able to drive the desired second sense current I2 anymore against the high resistive load Rs.

The second measurement circuit 214 may include a second sensing path 224 coupling the return terminal 206 and the common sensing terminal 210. The second sensing path may include a first current generator 226 and a second sense node 228. The first current generator 226 may generate the second sense current I2 such that the second parameter is generated at the second sense node 228 based on the drain voltage of the power switch 204. The second parameter may be a current or a voltage that is representative of the drain voltage present at the drain electrode. The first current generator 226 may be a voltage source with a series impedance that limits the second sense current I2 to a defined value, a current mirror combined with a reference current (where the reference current may be generated from a reference voltage drop on a resistance), a transconductance amplifier having an input voltage that sets the current value and shape for the second sense current I2, or any other type of current source.

The electrical return path 208 may provide a supply voltage to the second measurement circuit 214 during the second evaluation mode. The second sensing path 224 may include a second switch S2 that is closed to enable the second measurement circuit 214 and is opened to disable the second measurement circuit 214 based on a desired evaluation mode.

During the second evaluation mode (e.g., while the second measurement circuit 214 is enabled), the pn-junction diode Ds may allow the second sense current I2 to flow to the drain electrode 126 and through the power switch 204 to the source electrode 124 based on the drain voltage. Optionally, the auxiliary sense terminal 132 may be connected to the doped sensor region 128 to provide the resistive path.

The second measurement circuit 214 may compare the second parameter at the second sense node 228 with a first threshold, and detect an overcurrent condition of the power switch 204 based on the second parameter satisfying the first threshold. For example, the second measurement circuit 214 may detect the overcurrent condition based on the second parameter exceeding (e.g., being greater than) the first threshold. The second measurement circuit 214 may be configured to, for example, in conjunction with the gate driver or the controller, regulate the control signal of the power switch 204 based on the second parameter.

The third measurement circuit 216 may be configured to generate a third sense current I3 at the common sensing terminal 210, and measure the third parameter, which is generated based on the third sense current I3 and a temperature of the power switch 204. The third measurement circuit 216 may be configured to output the third sense current I3 (e.g., as a positive current) from the common sensing terminal 210 to the power switch 204, or may be configured to sink the third sense current I3 (e.g., as a negative current) to the common sensing terminal 210 from the power switch 204. In some implementations, the electrical return path 208 may enable the third sense current I3 to flow through the third measurement circuit 216 during the third evaluation mode.

The third measurement circuit 216 may include a third sensing path 230 coupling the return terminal 206 and the common sensing terminal 210. The third sensing path 230 may include a second current generator 232 and a third sense node 234. The second current generator 232 may be a voltage source, a current mirror combined with a reference current, a transconductance amplifier, or any other type of current source. The second current generator 232 may generate the third sense current I3 such that the third parameter is generated at the third sense node 234 based on the temperature of the power switch 204. The third parameter may be representative of an absolute temperature value of the temperature, and the third measurement circuit 216 may be configured to determine the absolute temperature value from the third parameter. In some implementations, the third parameter may be a voltage at the third sense node 234.

In some implementations, the second sense current I2 and the third sense current I3 may have an independent relationship to each other. For example, when the third evaluation mode is enabled during an off-state of the power switch 204, the third sense current I3 may have any current value. Thus, the third sense current I3 may be less than, equal to, or greater than the second sense current I2 when the third evaluation mode is enabled during the off-state of the power switch 204.

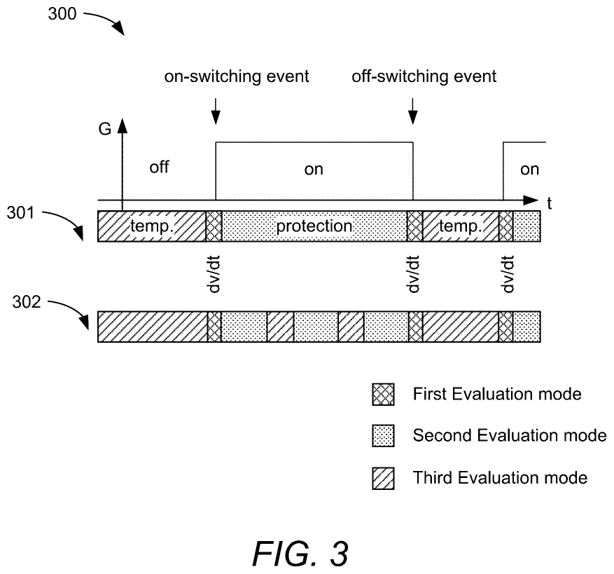

In some implementations, the third sense current I3 should be less than the second sense current I2. For example, when the third evaluation mode is enabled during an on-state of the power switch 204, the third sense current I3 should be less than the second sense current I2 (e.g., significantly less than the second sense current I2—an integer-multiple less than the second sense current I2, where the integer is greater than one). This would allow both the second evaluation mode and third evaluation mode to be both enabled during the on-state of the power switch 204, though not at the same time (e.g., see the second evaluation scheme 302 in FIG. 3). Thus, during the on-state of the power switch 204, the third measurement circuit 216 may be configured to generate the third sense current I3 in a first range, and the second measurement circuit 214 may be configured to generate the second sense current I2 in a second range that is higher than the first range. For example, the lower limit of the second range may be higher than the lower limit of the first range, and the upper limit of the second range may be higher than the upper limit of the first range. In some implementations, the first range and the second range do not overlap. In an example, the first range and the second range do not overlap, such that that the lower limit of the second range is higher than the upper limit of the first range. In addition, the third sense current I3 may be less than the second sense current I2. For example, the second sense current I2 may be between 50 μA and 1 mA, whereas the third sense current I3 may be between 10 μA and 500 μA. The third sense current I3 may be generated to be an integer-multiple less than the second sense current I2, where the integer is greater than one. For example, the third sense current I3 may be a factor of five times smaller than the second sense current I2 (e.g., I3 may be equal to one-fifth of I2). The third sensing path 230 may include a third switch S3 that is closed to enable the third measurement circuit 216 and is opened to disable the third measurement circuit 216 based on a desired evaluation mode.

During the third evaluation mode (e.g., while the third measurement circuit 216 is enabled), the integrated sensor 134 may allow the third sense current I3 to flow through the sensor region of the power switch 204 and cause the third parameter to be generated at the third sense node 234 based on the temperature in the sensor region. The auxiliary sense terminal 132 may be connected to the doped sensor region 128 to provide the resistive path (e.g., a temperature-dependent resistive path).

In some implementations, the temperature-dependent resistive path, coupled to the common sensing terminal 210 and formed by the doped sensor region 128, may be configured to conduct the third sense current I3, and generate the third parameter at the third sense node 234 (e.g., at the common sensing terminal 210) based on the temperature of the power switch 204. For example, a resistive value of the electrical resistance Rs may vary based on the temperature of the power switch 204, which may affect the voltage at the third sense node 234 according to Ohm's Law.

The third measurement circuit 216 may compare the third parameter at the third sense node 234 with a second threshold, and detect an overtemperature condition based on the third parameter satisfying the second threshold. For example, the third measurement circuit 216 may detect the overtemperature condition based on the third parameter exceeding (e.g., being greater than) the second threshold. The third measurement circuit 216 may be configured to, for example, in conjunction with the gate driver or the controller, regulate the control signal of the power switch 204 based on the third parameter.

During turn-on or turn-off switching events, switch S1 may be closed and the switches S2 and S3 may be opened. During a dV/dt phase, the junction capacitor Cs may provide a displacement current (e.g., the first sense current I1) to the evaluation circuit 202, and a voltage at the first sense node 220 may be provided to a further processing component. The controller or the gate driver may adjust a control signal (e.g., a gate current) to achieve a desired slope for dV/dt based on a measurement acquired from the first sense node 220. Part of the displacement current may flow via the resistive path (through Rs) to the source electrode, but most of the displacement current will flow into the first measurement circuit 212 due to the first measurement circuit 212 having a resistance that is significantly lower than Rs. Also in case of active current transducers, these active circuits can enable input resistance 0 Ohm.

After the power switch 204 is turned on (e.g., following a turn-on switching event), switches S1 and S3 may be opened and switch S2 may be closed for enabling the second evaluation mode. The second sense current I2 may be injected into the sense terminal 130 from the second measurement circuit 214. The pn-junction diode Ds may be implemented as a DESAT diode that is monolithically integrated into the power switch 204. As a result of the diode being monolithically integrated into the power switch 204, an additional high voltage connection is not needed, which allows additional external components that would have otherwise been needed to perform DESAT protection to be eliminated. A simple low voltage connection (e.g., in the domain of the gate voltage) with the gate driver or the evaluation circuit 202 is enough to perform overcurrent detection. Further, the only high voltage pin needed is the drain electrode 126 of the power switch 204, which in any case must be designed for a high voltage of a load or power supply. The second sense current I2 should be large enough that a majority of the second sense current I2 flows via pn-junction diode Ds to the drain of the power switch when Vds of the power switch is low enough. This condition may be fulfilled with second sense current I2 in a range of 50 μA to 1 mA. However, other current ranges may be used, depending on the configuration of the power switch 204. In the case of a short circuit or high overcurrent, Vds and thus the voltage at the second sense node 228 will rise, indicating a fault.

When the temperature of the power switch 204 is to be monitored (e.g., during an on-state and/or an off-state), switches S1 and S2 may be opened and switch S3 may be closed for enabling the third evaluation mode. The third sense current I3 may be generated, and a respective voltage drop at the third sense node 234 may be monitored. For the third evaluation mode, the third sense current I3 should be selected such that the voltage at the third sense node 234 remains below approximately 2.5 V when the power switch 204 is implemented as a SiC MOSFET, such that a majority of the third sense node 234 flows through Rs and only a negligible part of the third sense current I3 flows through pn-junction diode Ds. The diffusion voltage is approximately 0.4 to 0.8V lower than the bandgap of the semiconductor material in use. For Si, it is in the range of 0.5V (only small window for temp. measurement!), for GaN and SiC approx. 2.5 . . . 2.9V and for Ga2O3 around 3.7 . . . 4.5V. It can be lowered by parasitic elements like parasitic surface channels caused by interface defects and traps. The third sense current I3 may be selected based on a resistivity value of the resistive path Rs such that a voltage drop across the resistive path Rs does not exceed a forward voltage drop of the pn junction diode Ds during a normal operation of the power switch 204 (e.g., outside of switching transients and/or abnormal states, such as overload or short circuit). In addition, the second sense current I2 may be selected such that a voltage drop across the resistive path is larger than the forward voltage drop of the pn junction diode Ds during normal operation of the power switch. In some implementations, the third sense current I3 may be generated to be in a range of 10 μA to 500 μA. In some implementations, the third sense current I3 should not exceed ⅕ of the second sense current I2. As an alternative, a negative current can be injected into the sense terminal 130 such that the pn-junction diode Ds is in a blocking state, which may enable higher voltage drops or sensor signals at the expense of implementing a negative supply voltage in the third measurement circuit 216, which typically adds more complexity.

One significant advantage resultant from the connections shown in FIGS. 1 and 2 is that the evaluation circuit 202 may be connected to many different types of power switches that have different characteristics (e.g., different drain-source on resistance (RDS,on), different capacitive characteristic, different transconductance, different voltage class, etc.) so that all these different power switches can have a unified interface that is compatible with the evaluation circuit 202, which reduces a number of different (costly) designs for the integrated circuits used to realize the evaluation circuit 202. In other words, the single sense electrical connection, the single return electrical connection, and the integrated sensor enable the evaluation circuit 202 to be implemented for a wide range of power switches and other power devices. In some implementations, additional tuning in the evaluation circuit 202 may be necessary to adjust to a power device in use.

As indicated above, FIG. 2 is provided merely as an example. Other examples may differ from what is described with regard to FIG. 2. The number and arrangement of components shown in FIG. 2 are provided as an example. In practice, the system 200 may include additional components, fewer components, different components, or differently arranged components than those shown in FIG. 2. Two or more components shown in FIG. 2 may be implemented within a single component, or a single component shown in FIG. 2 may be implemented as multiple, distributed components. Additionally, or alternatively, a set of components (e.g., one or more components) of the system 200 may perform one or more functions described as being performed by another set of components of the system 200.

FIG. 3 shows a diagram 300 of example evaluation schemes relative to switching states of a power switch according to one or more implementations. The diagram 300 shows a first evaluation scheme 301 during which the first evaluation mode, the second evaluation mode, and the third evaluation mode are enabled at different phases or time intervals of the switching states of the power switch. The switching states (e.g., on transition-state, on-state, off transition-state, and off-state) are shown based on a gate voltage of the power switch.

Additionally, the diagram 300 shows a second evaluation scheme 302 during which the first evaluation mode, the second evaluation mode, and the third evaluation mode are enabled at different phases or time intervals of the switching states of the power switch. In the second evaluation scheme 302, the second evaluation mode and the third evaluation mode are toggled or interleaved during the on-state of the power switch.

Each of the first evaluation mode, the second evaluation mode, and the third evaluation mode may be enabled separately, in different time intervals. The integrated temperature sense may have a much faster response compared to external temperature sensors and, due to good thermal coupling inside the power switch without oxide interfaces, may be faster than conventional integrated temperature sensors that have a dielectric isolation to the semiconductor material. Due to this faster response, acute overload conditions can also be detected with the temperature sensor described in connection with FIGS. 1 and 2.

During a blocking operation of the power switch (e.g., during the off-state), overcurrent detection is not needed. Thus, third measurement circuit 216 may be enabled during the off-state of the power switch. If, for certain requirements, it is necessary to monitor the temperature also during forward operation of the power switch, the evaluation circuit 202 may toggle between the second evaluation mode and the third evaluation mode during the on-state of the power switch.

During a dV/dt phase at turn-on of a switch, the voltage in the power switch first has to drop below a clamping voltage of the first current generator 226 before the second measurement circuit 214 is operable. Therefore, a blanking time after the turn-on command of the gate driver may be enabled prior to the second measurement circuit 214 being enabled. As a result, using the first evaluation mode during this phase does not reduce the protection of the power switch. The time delay between raising the gate signal and dropping of the voltage below the clamping voltage of the first current generator 226 or lower at initial turn-on (e.g., at load current of zero) can be used to calibrate the evaluation circuit 202, the gate driver, and/or the controller to the parasitics of the application in consideration. Even more, in case of switching on to a high overcurrent or short circuit mode, the dV/dt at turn-on will be significantly slowed down due to the smaller voltage difference between the Miller voltage for conducting the load current and the maximum voltage of the gate driver. When dV/dt is not reaching an expected value during turn-on, a fault may be detected and can be used for additional, fast protection. Of course, the expected value should not be set too sharp to avoid erroneous triggering faults since during dV/dt parasitic capacitances or recovery charge of freewheeling elements during turn-on may lead to increased current levels which may exceed normal operation currents.

When the power switch 204 is turned on with a short circuit being present, first the voltage at the drain of the power switch 204 will drop, merely because of the voltage drop at the residual inductance of the short circuit. But then, the drain-source voltage will rise again. In case a pattern of a negative dV/dt followed shortly by a positive dV/dt is detected by the first measurement circuit 212, the first measurement circuit 212 may detect a short circuit of the load. The short circuit detection may include some filtering and avoidance of negative influence of measurement noise. Thus, the first measurement circuit 212 may evaluate a pattern of the dV/dt, and detect one or more types of overcurrent conditions (e.g., short circuit, etc.).

In an alternative setup, during a first dV/dt after start-up of the system, the first evaluation mode may be skipped and replaced by the second evaluation mode to verify whether the power switch is free of any defects, such as wiring defects and/or load defects, without a time delay required by a dead time between the evaluation modes. Here, a safe dV/dt or gate driving strength should be selected. Since this applies only for one or a few pulses for each power switch, the increased turn-on losses here do not impact an efficiency of the system in a noticeable way.

As indicated above, FIG. 3 is provided merely as an example. Other examples may differ from what is described with regard to FIG. 3.

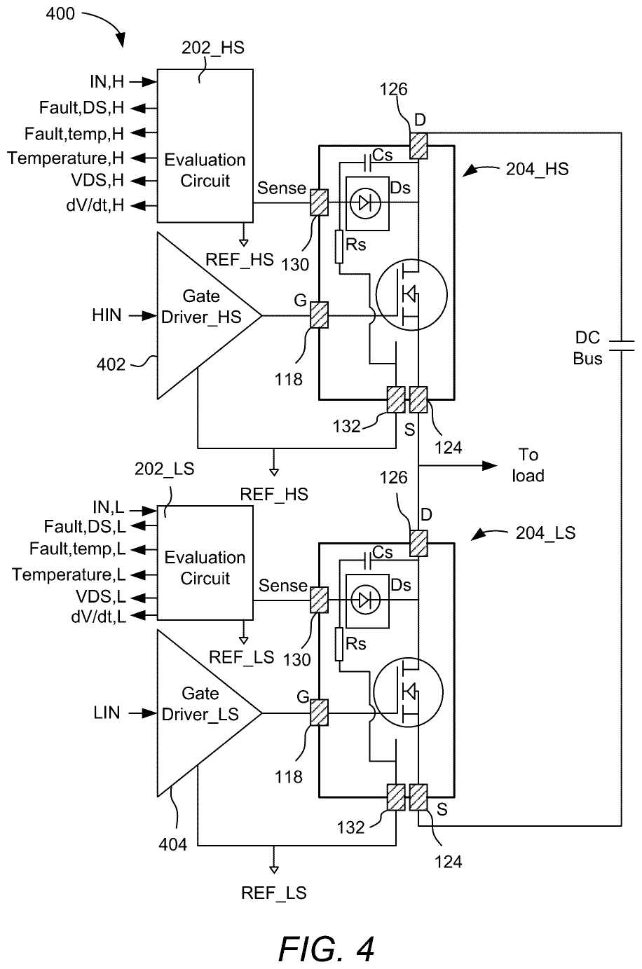

FIG. 4 shows a schematic diagram of a system 400 according to one or more implementations. The system 400 includes a transistor half-bridge that includes a high-side power switch 204_HS and a low-side power switch 204_LS connected to a load. The system 400 further includes a high-side gate driver 402 for driving the high-side power switch 204_HS between switching states based on a PWM control signal HIN received from a controller (not illustrated), and low-side gate driver 404 for driving the low-side power switch 204_LS between switching states based on a PWM control signal LIN received from the controller.

The auxiliary sense terminal 132 of each power switch may be connected to a reference supply of a gate driver. For example, the auxiliary sense terminal 132 of the high-side power switch 204_HS may be connected to a reference supply (e.g., ground) REF_HS of the high-side gate driver 402. The auxiliary sense terminal 132 of the low-side power switch 204_LS may be connected to a reference supply (e.g., ground) REF_LS of the low-side gate driver 404.

The system 400 further includes a high-side evaluation circuit 202_HS for evaluating one or more parameters of the high-side power switch 204_HS, and a low-side-evaluation circuit 202_LS for evaluating one or more parameters of the low-side power switch 204_LS. The high-side evaluation circuit 202_HS may receive a mode control signal IN, H from the controller or the high-side gate driver 402 indicating an evaluation mode, and may enable the first evaluation mode, the second evaluation mode, or the third evaluation mode based on the mode control signal IN,H. The high-side evaluation circuit 202_HS may generate one or more measurement signals and/or fault signals based on the evaluation mode and one or more measurement results (e.g., fault, DS,H; fault, temp,H; temperature, H; Vds,H; dV/dt,H). The low-side evaluation circuit 202_LS may receive a mode control signal IN,L from the controller or the low-side gate driver 404 indicating an evaluation mode, and may enable the first evaluation mode, the second evaluation mode, or the third evaluation mode based on the mode control signal IN,L. The low-side evaluation circuit 202_LS may generate one or more measurement signals and/or fault signals based on the evaluation mode and one or more measurement results (e.g., fault, DS,L; fault, temp,L; temperature,L; Vds,L; dV/dt,L). For example, the high-side evaluation circuit 202_HS and the low-side evaluation circuit 202_LS may generate fault, DS,x in a case where a drain-source voltage Vds is higher than expected, fault, temp,x in a case where a junction temperature higher than expected, temperature,x that is an analog or digital information signal that represents a measured junction temperature, Vds,x that represents a value of the drain-source voltage Vds that can be used to determine the voltage transient dV/dt, and dV/dt,x that represents the slew-rate, which may be calculated by the evaluation circuit based on, for example, Vds,x. Here, “x” is a placeholder for H or L, and “higher than expected” means “exceeds a respective threshold.”

As indicated above, FIG. 4 is provided merely as an example. Other examples may differ from what is described with regard to FIG. 4. The number and arrangement of components shown in FIG. 4 are provided as an example. In practice, the system 400 may include additional components, fewer components, different components, or differently arranged components than those shown in FIG. 4. Two or more components shown in FIG. 4 may be implemented within a single component, or a single component shown in FIG. 4 may be implemented as multiple, distributed components. Additionally, or alternatively, a set of components (e.g., one or more components) of the system 400 may perform one or more functions described as being performed by another set of components of the system 400.

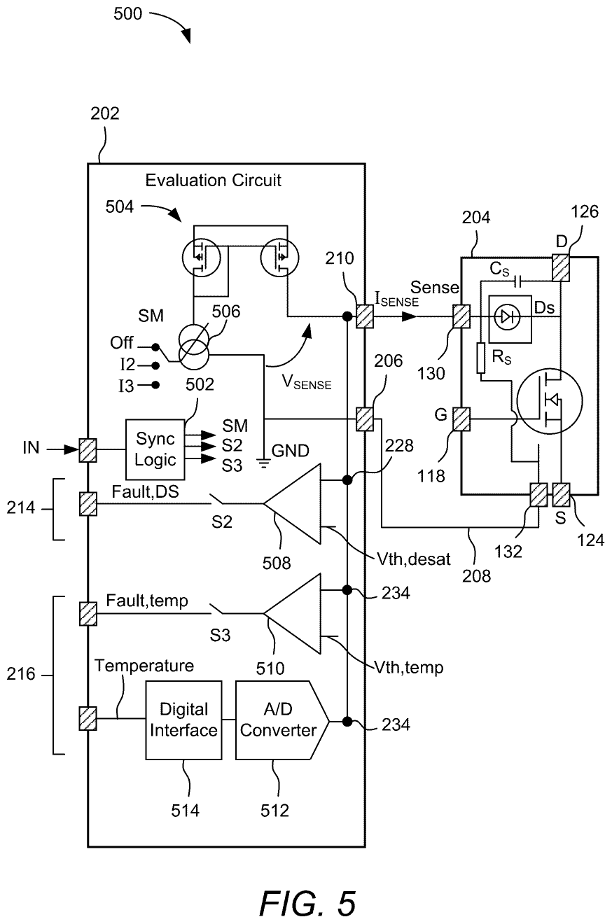

FIG. 5 shows a schematic diagram of a system 500 according to one or more implementations. The system 500 includes the evaluation circuit 202 and the power switch 204. The evaluation circuit 202 may include a mode switch SM, a switch control circuit 502, a current mirror 504, and a reference current generator 506, which may be combined to form a configurable current source. The switch control circuit 502 may receive a mode control signal IN that indicates an evaluation mode, and generate one or more switch control signals for controlling the mode switch SM, the second switch S2, and the third switch S3 based on the mode control signal IN. The mode switch SM may connect the reference current generator 506 to different control values, including an off control value, during which the reference current generator 506 generates no current; an I2 control value, during which the reference current generator 506 generates a reference current corresponding to the second sense current I2; and an I3 control value, during which the reference current generator 506 generates a reference current corresponding to the third sense current I3. The I3 control value may be less than the I2 control value. For example, the I3 control value may be less than one-fifth of the I2 control value.

The current mirror 504 may inject a sense current Isense into the sense terminal 130 of the power switch 204 based on the position of the mode switch SM. For example, the current mirror 504 may generate the second sense current I2 when the mode switch SM is in an I2 position, and may generate the third sense current I3 when the mode switch SM is in an I3 position. In some implementations, placing the mode switch SM in an off position disables the sensing functionality of the evaluation circuit 202, for example, in a case when the first evaluation circuit is 212 is not present. In some implementations, when the first evaluation circuit 212 is present, placing the mode switch SM in an off position may enable the evaluation circuit 202 to receive the first sense current I1 at the common sensing terminal 210 from the power switch 204 (e.g., for the first evaluation mode).

A sense voltage Vsense may be generated at the common sensing terminal 210 during the different evaluation modes. For example, the sense current Isense causes the sense voltage Vsense to be equal to a forward voltage of the pn-junction diode Ds during the second evaluation mode, and causes the sense voltage Vsense to be equal to RsxIsense during the third evaluation mode.

The second measurement circuit 214 of the evaluation circuit 202 may include a comparator 508 that compares the sense voltage Vsense to a threshold Vth,desat, and generates a fault signal fault, DS (e.g., a logic high signal) when the sense voltage Vsense exceeds the threshold Vth,desat. The second measurement circuit 214 may provide the fault signal fault, DS to the gate driver or the controller. The gate driver may decide to turn the power switch 204 off as soon as the respective threshold is crossed, or with a certain delay depending on some filtering functions.

An overcurrent event may occur when the drain voltage rises due to an overload drain current condition. This makes the sense voltage Vsense increase up to a point where the pn-junction diode Ds opens and the entire injected sense current Isense flows through the electrical return path 208 (e.g., through the electrical resistance Rs), instead of at least a portion of the sense current Isense flowing through the pn-junction diode Ds to the drain. As a result, the sense voltage Vsense becomes equal to 12×Rs, which is greater than the threshold Vth,desat.

The third measurement circuit 216 of the evaluation circuit 202 may include a comparator 510 that compares the sense voltage Vsense to a threshold Vth,temp, and generates a fault signal fault, temp (e.g., a logic high signal) when the sense voltage Vsense exceeds the threshold Vth,temp. The third measurement circuit 216 may provide the fault signal fault, temp to the gate driver or the controller. The gate driver may decide to turn the power switch 204 off as soon as the respective threshold is crossed or with a certain delay depending on some filtering functions.

The third measurement circuit 216 of the evaluation circuit 202 may include an analog-to-digital converter (ADC) 512 and digital interface 514. The ADC 512 may convert the sense voltage Vsense into a digital signal (e.g., a digital value) that may represent an absolute temperature of the power switch 204. The digital value may represent the resistive value of the electrical resistance Rs. The digital interface 514 may include a look-up table, and may output the absolute temperature based on the digital value provided by the ADC 512.

Each measurement circuit 212, 214, and 216 may further include analog and/or digital filtering to, for example, improve signal quality.

As indicated above, FIG. 5 is provided merely as an example. Other examples may differ from what is described with regard to FIG. 5. The number and arrangement of components shown in FIG. 5 are provided as an example. In practice, the system 500 may include additional components, fewer components, different components, or differently arranged components than those shown in FIG. 5. Two or more components shown in FIG. 5 may be implemented within a single component, or a single component shown in FIG. 5 may be implemented as multiple, distributed components. Additionally, or alternatively, a set of components (e.g., one or more components) of the system 500 may perform one or more functions described as being performed by another set of components of the system 500.

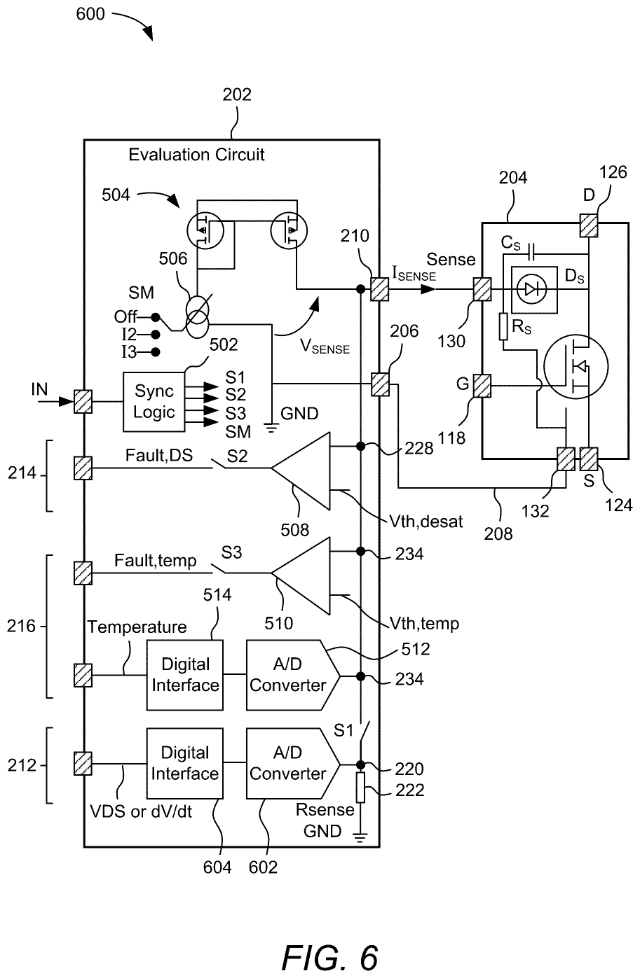

FIG. 6 shows a schematic diagram of a system 600 according to one or more implementations. The system 600 includes the evaluation circuit 202 and the power switch 204. The evaluation circuit 202 includes the first measurement circuit 212 and an additional switch state at the switch control circuit 502 for the first switch S1. The first switch S1 may be closed when the switch control circuit 502 sets the mode switch SM into the off position, and may be open when the switch control circuit 502 sets the mode switch SM into the I2 position or the I3 position. The first measurement circuit 212 may include the resistive element 222, which may be used as a sense resistor Rsense. In addition, the first measurement circuit 212 may include an ADC 602 and a digital interface 604. The ADC 602 may convert the sense voltage Vsense into a digital signal (e.g., a digital value) that may represent the drain voltage or the drain-source voltage of the switch 204. The digital interface 604 may evaluate the digital signal over a predetermined interval to calculate a slew-rate (e.g., a rate-of-change) or slope of the drain voltage (e.g., dV/dt), or may provide the digital signal to the gate driver or the controller.

The gate driver or the controller may compare the slew-rate to one or more set-points (e.g., thresholds), and may increase or reduce the slew-rate by tuning the control signal provided to the gate electrode 118.

In some implementations, a blanking time is included at the rising edge of the mode control signal IN in order to keep the mode switch SM in the off position and enable the first measurement circuit 212 during the blanking time. The first switch S1, the second switch S2, and the third switch S3 may be driven according to the first evaluation scheme 301 or the second evaluation scheme 302 described in connection with FIG. 3.

In some implementations, the second measurement circuit 214 or the third measurement circuit 216 may not be present.

Each measurement circuit 212, 214, and 216 may further include analog and/or digital filtering to, for example, improve signal quality.

As indicated above, FIG. 6 is provided merely as an example. Other examples may differ from what is described with regard to FIG. 6. The number and arrangement of components shown in FIG. 6 are provided as an example. In practice, the system 600 may include additional components, fewer components, different components, or differently arranged components than those shown in FIG. 6. Two or more components shown in FIG. 6 may be implemented within a single component, or a single component shown in FIG. 6 may be implemented as multiple, distributed components. Additionally, or alternatively, a set of components (e.g., one or more components) of the system 600 may perform one or more functions described as being performed by another set of components of the system 600.

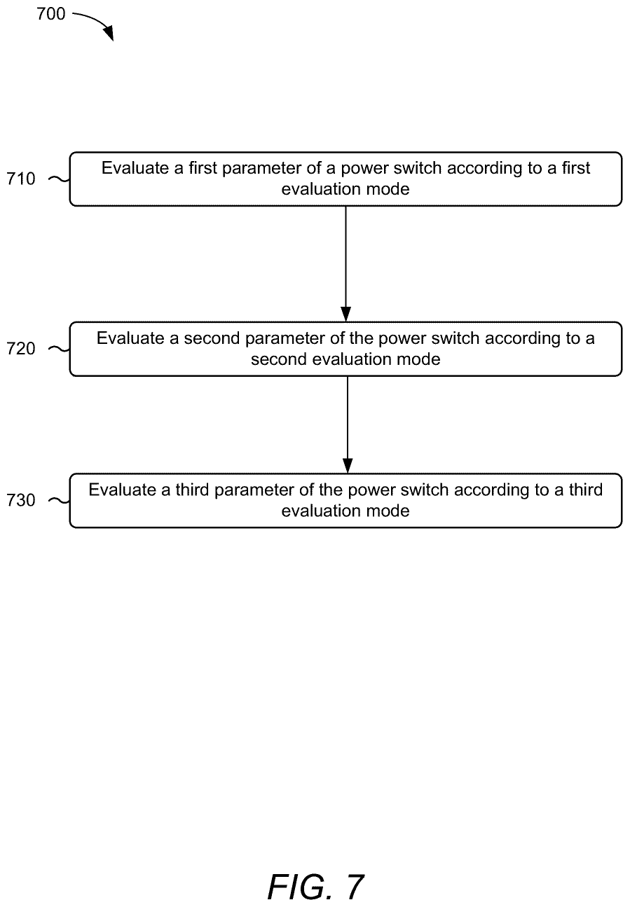

FIG. 7 is a flowchart of an example process 700 associated with evaluation circuit for a power device with an integrated sensor. In some implementations, one or more process blocks of FIG. 7 are performed by an evaluation circuit (e.g., evaluation circuit 202). In some implementations, one or more process blocks of FIG. 7 are performed by another device or a group of devices separate from or including the evaluation circuit, such as a gate driver or a controller. Additionally, or alternatively, one or more process blocks of FIG. 7 may be performed in conjunction with a power device, such as power switch 204.

As shown in FIG. 7, process 700 may include evaluating a first parameter of a power switch according to a first evaluation mode (block 710). Evaluating the first parameter may include receiving a first sense current at a common sensing terminal from the power switch; and measuring the first parameter during a switching event of the power switch based on the first sense current. For example, the evaluation circuit 202 may evaluate the first parameter, as described above.

As further shown in FIG. 7, process 700 may include evaluating a second parameter of the power switch according to a second evaluation mode (block 720). Evaluating the second parameter may include generating a second sense current; outputting the second sense current from the common sensing terminal to the power switch; and measuring the second parameter, which is dependent on a current flow of the second sense current through the power switch, wherein the current flow depends on an electrode voltage present at a drain or a collector of the power switch. For example, the evaluation circuit 202 may evaluate the first parameter, as described above.

As further shown in FIG. 7, process 700 may include evaluating a third parameter of the power switch according to a third evaluation mode (block 730). Evaluating the third parameter may include generating a third sense current at the common sensing terminal; and measuring the third parameter, which is generated based on the third sense current and a temperature of the power switch. For example, the evaluation circuit 202 may evaluate the third parameter, as described above.

Process 700 may include additional implementations, such as any single implementation or any combination of implementations described below and/or in connection with one or more other processes described elsewhere herein.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

The following provides an overview of some Aspects of the present disclosure:
Aspect 1: A system, comprising: an evaluation circuit configured to evaluate a first parameter of a power switch according to a first evaluation mode and evaluate a second parameter of the power switch according to a second evaluation mode, the evaluation circuit comprising: a return terminal configured to be coupled to an auxiliary sense terminal of the power switch; a common sensing terminal configured to be coupled to a sense terminal of the power switch; a first measurement circuit coupled to the return terminal and the common sensing terminal, and configured to operate during the first evaluation mode, wherein the first measurement circuit is configured to receive a first sense current at the common sensing terminal from the power switch, and measure the first parameter during a switching event of the power switch based on the first sense current; and a second measurement circuit coupled to the return terminal and the common sensing terminal, and configured to operate during the second evaluation mode, wherein the second measurement circuit is configured to output a second sense current from the common sensing terminal to the power switch, and measure the second parameter, which is dependent on a current flow of the second sense current through the power switch, and wherein the current flow of the second sense current through the power switch depends on an electrode voltage present at a second load electrode of the power switch.
Aspect 2: The system of Aspect 1, wherein a first load electrode of the power switch is a source or an emitter, and the second load electrode is a drain or a collector.
Aspect 3: The system of any of Aspects 1-2, wherein the first parameter is representative of a rate-of-change of the electrode voltage present at the second load electrode.
Aspect 4: The system of Aspect 3, wherein the first measurement circuit is configured to regulate a control signal of the power switch based on the first parameter, detect a short circuit based first parameter, adapt a dead time of the power switch based on the first parameter, detect a working region of the power switch based on the first parameter, or monitor a status of the power switch based on the first parameter.
Aspect 5: The system of any of Aspects 1-4, wherein the switching event is a turn-on switching event, during which the power switch is transitioned from an off-state to an on-state, or wherein the switching event is a turn-off switching event, during which the power switch is transitioned from the on-state to the off-state.
Aspect 6: The system of any of Aspects 1-5, wherein the second parameter is representative of the electrode voltage present at the second load electrode.
Aspect 7: The system of any of Aspects 1-6, wherein the second measurement circuit includes a second sensing path coupled between the return terminal and the common sensing terminal, wherein the second sensing path includes a first current generator and a second sense node, and wherein the first current generator is configured to generate the second sense current such that the second parameter is generated at the second sense node based on the electrode voltage of the power switch.
Aspect 8: The system of Aspect 7, wherein the second measurement circuit is configured to compare the second parameter at the second sense node with a first threshold, and detect an overcurrent condition of the power switch based on the second parameter satisfying the first threshold.
Aspect 9: The system of any of Aspects 1-8, wherein the evaluation circuit is configured to evaluate a third parameter of the power switch according to a third evaluation mode, the evaluation circuit further comprising: a third measurement circuit coupled to the return terminal and the common sensing terminal, and configured to operate during the third evaluation mode, wherein the third measurement circuit is configured to generate a third sense current at the common sensing terminal, and measure the third parameter, which is generated based on the third sense current and a temperature of the power switch.
Aspect 10: The system of Aspect 9, wherein the third measurement circuit is configured to output the third sense current from the common sensing terminal to the power switch, or wherein the third measurement circuit is configured to sink the third sense current to the common sensing terminal from the power switch.
Aspect 11: The system of Aspect 9, wherein the third measurement circuit includes a third sensing path coupled between the return terminal and the common sensing terminal, wherein the third sensing path includes a second current generator and a third sense node, and wherein the second current generator is configured to generate the third sense current such that the third parameter is generated at the third sense node based on the temperature of the power switch.
Aspect 12: The system of Aspect 11, wherein the third parameter is representative of an absolute temperature value of the temperature, and the third measurement circuit is configured to determine the absolute temperature value from the third parameter.
Aspect 13: The system of Aspect 11, wherein the third measurement circuit is configured to compare the third parameter at the third sense node with a second threshold, and detect an overtemperature condition based on the third parameter satisfying the second threshold.
Aspect 14: The system of any of Aspects 1-13, further comprising the power switch, and wherein the power switch includes: a semiconductor body comprising a drift region, a transistor cell region at least partially integrated in the drift region, and a doped sensor region integrated in the drift region, wherein the doped sensor region is electrically coupled to the common sensing terminal, wherein the doped sensor region and the drift region form a junction capacitor that is electrically coupled to the common sensing terminal and the second load electrode of the power switch, and wherein the doped sensor region and the drift region form a pn-junction diode having an anode that is electrically coupled to the common sensing terminal and a cathode that is electrically coupled to the second load electrode of the power switch.
Aspect 15: The system of Aspect 14, wherein the power switch has a blocking voltage of at least 300 V.
Aspect 16: The system of Aspect 14, wherein the evaluation circuit and the power switch are integrated on separate dies.
Aspect 17: The system of Aspect 14, wherein the return terminal is coupled to an electrical return path that is coupled to the auxiliary sense terminal of the power switch, and wherein the electrical return path is configured to enable the first sense current to flow through the first measurement circuit during the first evaluation mode, and provide a supply voltage to the second measurement circuit during the second evaluation mode.
Aspect 18: The system of Aspect 14, wherein the doped sensor region is doped complementary to the drift region.
Aspect 19: The system of Aspect 14, wherein the junction capacitor is configured to, during the switching event, provide the first sense current to the common sensing terminal.
Aspect 20: The system of Aspect 14, wherein the pn-junction diode is configured to conduct the second sense current based on the electrode voltage of the power switch.
Aspect 21: The system of Aspect 14, wherein the auxiliary sense terminal is connected to the doped sensor region to provide a resistive path to the common sense terminal via the doped sensor region.
Aspect 22: The system of Aspect 21, wherein the auxiliary sense terminal is a first load electrode of the power switch.
Aspect 23: The system of Aspect 14, wherein the evaluation circuit is configured to evaluate a third parameter of the power switch according to a third evaluation mode, the evaluation circuit further comprising: a third measurement circuit coupled to the return terminal and the common sensing terminal, and configured to operate during the third evaluation mode, wherein the third measurement circuit is configured to generate a third sense current at the common sensing terminal, and measure the third parameter, which is generated based on a third sense current and the temperature of the power switch, wherein a temperature-dependent resistive path, coupled to the common sensing terminal and formed by the doped sensor region, is configured to conduct the third sense current, and generate the third parameter at the third measurement circuit based on the temperature of the power switch, and wherein the third parameter is a voltage corresponding to the temperature.
Aspect 24: A system, comprising: an evaluation circuit configured to evaluate a first parameter of a power switch according to a first evaluation mode and evaluate a second parameter of the power switch according to a second evaluation mode, the evaluation circuit comprising: a return terminal configured to be coupled to an auxiliary sense terminal of the power switch; a common sensing terminal configured to be coupled to a sense terminal of the power switch; a first measurement circuit coupled to the return terminal and the common sensing terminal, and configured to operate during the first evaluation mode, wherein the first measurement circuit is configured to receive a first sense current at the common sensing terminal from the power switch, and measure the first parameter during a switching event of the power switch based on the first sense current; and a second measurement circuit coupled to the return terminal and the common sensing terminal, and configured to operate during the second evaluation mode, wherein the second measurement circuit is configured to generate a second sense current at the common sensing terminal, and measure the second parameter, which is generated based on the second sense current and a temperature of the power switch.
Aspect 25: A system, comprising: an evaluation circuit configured to evaluate a first parameter of a power switch according to a first evaluation mode and evaluate a second parameter of the power switch according to a second evaluation mode, the evaluation circuit comprising: a return terminal configured to be coupled to an auxiliary sense terminal of the power switch; a common sensing terminal configured to be coupled to a sense terminal of the power switch; a first measurement circuit coupled to the return terminal and the common sensing terminal, and configured to operate during the first evaluation mode, wherein the first measurement circuit is configured to generate a first sense current at the common sensing terminal, and measure the first parameter, which is generated based on the first sense current and a temperature of the power switch; and a second measurement circuit coupled to the return terminal and the common sensing terminal, and configured to operate during the second evaluation mode, wherein the second measurement circuit is configured to output a second sense current from the common sensing terminal to the power switch, and measure the second parameter, which is dependent on a current flow of the second sense current through the power switch, and wherein the current flow of the second sense current through the power switch depends on an electrode voltage present at a second load electrode of the power switch.
Aspect 26: The system of Aspect 25, wherein the first sense current is less than the second sense current during an on-state of the power switch, and wherein the first sense current and the second sense current have an independent relationship during an off-state of the power switch.
Aspect 27: A method, comprising: evaluating a first parameter of a power switch according to a first evaluation mode, including: receiving a first sense current at a common sensing terminal from the power switch; and measuring the first parameter during a switching event of the power switch based on the first sense current; evaluating a second parameter of the power switch according to a second evaluation mode, including: generating a second sense current; outputting the second sense current from the common sensing terminal to the power switch; and measuring the second parameter, which is dependent on a current flow of the second sense current through the power switch, wherein the current flow depends on an electrode voltage present at a drain or a collector of the power switch; and evaluating a third parameter of the power switch according to a third evaluation mode, including: generating a third sense current at the common sensing terminal; and measuring the third parameter, which is generated based on the third sense current and a temperature of the power switch.
Aspect 28: The method of Aspect 27, wherein the first evaluation mode is enabled during a turn-on switching event and a turn-off switching event of the power switch, the second evaluation mode is enabled during an on-state of the power switch, and the third evaluation mode is enabled during an off-state of the power switch.
Aspect 29: The method of any of Aspects 27-28, wherein the second sense current and the third sense current are a same current.
Aspect 30: The method of Aspect 27, wherein the first evaluation mode is enabled during a turn-on switching event and a turn-off switching event of the power switch, the second evaluation mode is enabled during an on-state of the power switch, and the third evaluation mode is enabled during the on-state of the power switch and during an off-state of the power switch, wherein, during the on-state of the power switch, the second evaluation mode and the third evaluation mode are enabled in interleaved time slots such that the second evaluation mode and the third evaluation mode are alternately enabled.
Aspect 31: The method of any of Aspects 27-30, wherein, during a first turn-on switching event following a system start-up, the second evaluation is enabled and the first and third evaluation modes are disabled.
Aspect 32: The method of any of Aspects 27-31, wherein the first parameter is a voltage transient dV/dt of an electrode voltage of the power switch, and wherein evaluating the first parameter of the power switch includes evaluating a pattern of the first parameter, and detecting an overcurrent based on the pattern satisfying an overcurrent condition.
Aspect 33: The method of any of Aspects 27-32, wherein the first parameter is a voltage transient dV/dt of an electrode voltage of the power switch, and wherein evaluating the first parameter of the power switch includes evaluating a pattern of the first parameter during a turn-on switching event of the power switch, and detecting a short circuit based on the pattern indicating a negative voltage transient followed by a positive voltage transient.
Aspect 34: A system configured to perform one or more operations recited in one or more of Aspects 1-33.
Aspect 35: An apparatus comprising means for performing one or more operations recited in one or more of Aspects 1-33.
Aspect 36: A non-transitory computer-readable medium storing a set of instructions, the set of instructions comprising one or more instructions that, when executed by a device, cause the device to perform one or more operations recited in one or more of Aspects 1-33.
Aspect 37: A computer program product comprising instructions or code for executing one or more operations recited in one or more of Aspects 1-33.

The foregoing disclosure provides illustration and description, but is not intended to be exhaustive or to limit the implementations to the precise form disclosed. Modifications and variations may be made in light of the above disclosure or may be acquired from practice of the implementations.

Some implementations may be described herein in connection with thresholds. As used herein, “satisfying” a threshold may refer to a value being greater than the threshold, more than the threshold, higher than the threshold, greater than or equal to the threshold, less than the threshold, fewer than the threshold, lower than the threshold, less than or equal to the threshold, equal to the threshold, or the like.

As used herein, the term “component” is intended to be broadly construed as hardware, firmware, or a combination of hardware and software. Systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

Any of the processing components may be implemented as a central processing unit (CPU) or other processor reading and executing a software program from a non-transitory computer-readable recording medium such as a hard disk or a semiconductor memory device. For example, instructions may be executed by one or more processors, such as one or more CPUs, digital signal processors (DSPs), general-purpose microprocessors, application-specific integrated circuits (ASICs), field programmable logic arrays (FPLAs), programmable logic controller (PLC), or other equivalent integrated or discrete logic circuitry. Accordingly, the term “processor,” as used herein, refers to any of the foregoing structures or any other structure suitable for implementation of the techniques described herein. Software may be stored on a non-transitory computer-readable medium such that the non-transitory computer readable medium includes program code or a program algorithm stored thereon that, when executed, causes the processor, via a computer program, to perform the steps of a method.

A controller including hardware may also perform one or more of the techniques of this disclosure. A controller, including one or more processors, may use electrical signals and digital algorithms to perform its receptive, analytic, and control functions, which may further include corrective functions. Such hardware, software, and firmware may be implemented within the same device or within separate devices to support the various techniques described in this disclosure.

A signal processing circuit and/or a signal conditioning circuit may receive one or more signals (e.g., measurement signals) from one or more components in the form of raw measurement data and may derive, from the measurement signal, further information. “Signal conditioning,” as used herein, refers to manipulating an analog signal in such a way that the signal meets the requirements of a next stage for further processing. Signal conditioning may include converting from analog to digital (e.g., via an analog-to-digital converter), amplification, filtering, converting, biasing, range matching, isolation, and any other processes required to make a signal suitable for processing after conditioning.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a and b, a and c, b and c, and a, b, and c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

Further, it is to be understood that the disclosure of multiple acts or functions disclosed in the specification or in the claims may not be construed as to be within the specific order. Therefore, the disclosure of multiple acts or functions will not limit these to a particular order unless such acts or functions are not interchangeable for technical reasons. Furthermore, in some implementations, a single act may include or may be broken into multiple sub acts. Such sub acts may be included and part of the disclosure of this single act unless explicitly excluded.

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

1. A system, comprising:
an evaluation circuit configured to evaluate a first parameter of a power switch according to a first evaluation mode and evaluate a second parameter of the power switch according to a second evaluation mode, the evaluation circuit comprising:
a return terminal configured to be coupled to an auxiliary sense terminal of the power switch;
a common sensing terminal configured to be coupled to a sense terminal of the power switch;
a first measurement circuit coupled to the return terminal and the common sensing terminal, and configured to operate during the first evaluation mode,
wherein the first measurement circuit is configured to receive a first sense current at the common sensing terminal from the power switch, and measure the first parameter during a switching event of the power switch based on the first sense current; and
a second measurement circuit coupled to the return terminal and the common sensing terminal, and configured to operate during the second evaluation mode,
wherein the second measurement circuit is configured to output a second sense current from the common sensing terminal to the power switch, and measure the second parameter, which is dependent on a current flow of the second sense current through the power switch, and
wherein the current flow of the second sense current through the power switch depends on an electrode voltage present at a second load electrode of the power switch.

2. The system of claim 1, wherein a first load electrode of the power switch is a source or an emitter, and the second load electrode is a drain or a collector.

3. The system of claim 1, wherein the first parameter is representative of a rate-of-change of the electrode voltage present at the second load electrode.

4. The system of claim 3, wherein the first measurement circuit is configured to regulate a control signal of the power switch based on the first parameter, detect a short circuit based on the first parameter, adapt a dead time of the power switch based on the first parameter, detect a working region of the power switch based on the first parameter, or monitor a status of the power switch based on the first parameter.

5. The system of claim 1, wherein the switching event is a turn-on switching event, during which the power switch is transitioned from an off-state to an on-state, or
wherein the switching event is a turn-off switching event, during which the power switch is transitioned from the on-state to the off-state.

6. The system of claim 1, wherein the second parameter is representative of the electrode voltage present at the second load electrode.

7. The system of claim 1, wherein the second measurement circuit includes a second sensing path coupled between the return terminal and the common sensing terminal,
wherein the second sensing path includes a first current generator and a second sense node, and
wherein the first current generator is configured to generate the second sense current such that the second parameter is generated at the second sense node based on the electrode voltage of the power switch.

8. The system of claim 7, wherein the second measurement circuit is configured to compare the second parameter at the second sense node with a first threshold, and detect an overcurrent condition of the power switch based on the second parameter satisfying the first threshold.

9. The system of claim 1, wherein the evaluation circuit is configured to evaluate a third parameter of the power switch according to a third evaluation mode, the evaluation circuit further comprising:
a third measurement circuit coupled to the return terminal and the common sensing terminal, and configured to operate during the third evaluation mode,
wherein the third measurement circuit is configured to generate a third sense current at the common sensing terminal, and measure the third parameter, which is generated based on the third sense current and a temperature of the power switch.

10. The system of claim 9, wherein the third measurement circuit is configured to output the third sense current from the common sensing terminal to the power switch, or
wherein the third measurement circuit is configured to sink the third sense current to the common sensing terminal from the power switch.

11. The system of claim 9, wherein the third measurement circuit includes a third sensing path coupled between the return terminal and the common sensing terminal,
wherein the third sensing path includes a second current generator and a third sense node, and
wherein the second current generator is configured to generate the third sense current such that the third parameter is generated at the third sense node based on the temperature of the power switch.

12. The system of claim 11, wherein the third parameter is representative of an absolute temperature value of the temperature, and the third measurement circuit is configured to determine the absolute temperature value from the third parameter.

13. The system of claim 11, wherein the third measurement circuit is configured to compare the third parameter at the third sense node with a second threshold, and detect an overtemperature condition based on the third parameter satisfying the second threshold.

14. The system of claim 1, further comprising the power switch, and wherein the power switch includes:
a semiconductor body comprising a drift region, a transistor cell region at least partially integrated in the drift region, and a doped sensor region integrated in the drift region,
wherein the doped sensor region is electrically coupled to the common sensing terminal,
wherein the doped sensor region and the drift region form a junction capacitor that is electrically coupled to the common sensing terminal and the second load electrode of the power switch, and
wherein the doped sensor region and the drift region form a pn-junction diode having an anode that is electrically coupled to the common sensing terminal and a cathode that is electrically coupled to the second load electrode of the power switch.

15. (canceled)

16. (canceled)

17. The system of claim 14, wherein the return terminal is coupled to an electrical return path that is coupled to the auxiliary sense terminal of the power switch, and
wherein the electrical return path is configured to enable the first sense current to flow through the first measurement circuit during the first evaluation mode, and provide a supply voltage to the second measurement circuit during the second evaluation mode.

18. The system of claim 14, wherein the doped sensor region is doped complementary to the drift region.

19. (canceled)

20. (canceled)

21. The system of claim 14, wherein the auxiliary sense terminal is connected to the doped sensor region to provide a resistive path to the common sense terminal via the doped sensor region.

22. (canceled)

23. The system of claim 14, wherein the evaluation circuit is configured to evaluate a third parameter of the power switch according to a third evaluation mode, the evaluation circuit further comprising:
a third measurement circuit coupled to the return terminal and the common sensing terminal, and configured to operate during the third evaluation mode,
wherein the third measurement circuit is configured to generate a third sense current at the common sensing terminal, and measure the third parameter, which is generated based on the third sense current and a temperature of the power switch,
wherein a temperature-dependent resistive path, coupled to the common sensing terminal and formed by the doped sensor region, is configured to conduct the third sense current, and generate the third parameter at the third measurement circuit based on the temperature of the power switch, and
wherein the third parameter is a voltage corresponding to the temperature.

24. A system, comprising:
an evaluation circuit configured to evaluate a first parameter of a power switch according to a first evaluation mode and evaluate a second parameter of the power switch according to a second evaluation mode, the evaluation circuit comprising:
a return terminal configured to be coupled to an auxiliary sense terminal of the power switch;
a common sensing terminal configured to be coupled to a sense terminal of the power switch;
a first measurement circuit coupled to the return terminal and the common sensing terminal, and configured to operate during the first evaluation mode,
wherein the first measurement circuit is configured to receive a first sense current at the common sensing terminal from the power switch, and measure the first parameter during a switching event of the power switch based on the first sense current; and
a second measurement circuit coupled to the return terminal and the common sensing terminal, and configured to operate during the second evaluation mode,
wherein the second measurement circuit is configured to generate a second sense current at the common sensing terminal, and measure the second parameter, which is generated based on the second sense current and a temperature of the power switch.

25. A system, comprising:
an evaluation circuit configured to evaluate a first parameter of a power switch according to a first evaluation mode and evaluate a second parameter of the power switch according to a second evaluation mode, the evaluation circuit comprising:
a return terminal configured to be coupled to an auxiliary sense terminal of the power switch;
a common sensing terminal configured to be coupled to a sense terminal of the power switch;
a first measurement circuit coupled to the return terminal and the common sensing terminal, and configured to operate during the first evaluation mode,
wherein the first measurement circuit is configured to generate a first sense current at the common sensing terminal, and measure the first parameter, which is generated based on the first sense current and a temperature of the power switch; and
a second measurement circuit coupled to the return terminal and the common sensing terminal, and configured to operate during the second evaluation mode,
wherein the second measurement circuit is configured to output a second sense current from the common sensing terminal to the power switch, and measure the second parameter, which is dependent on a current flow of the second sense current through the power switch, and
wherein the current flow of the second sense current through the power switch depends on an electrode voltage present at a second load electrode of the power switch.

26. (canceled)

27. (canceled)
